(19) United States
(12) Patent Application Publication
(10) Pub. No.: US 2026/0277043 A1
(43) Pub. Date: Sep. 17, 2026

(54) DISPLAY MODULE AND ELECTRONIC DEVICE INCLUDING THEREOF

(71) Applicant: Samsung Display Co., Ltd., Yongin-si (KR)

(72) Inventors: WOOYOUNG KIM, Yongin-si (KR); SU JEONG KIM, Yongin-si (KR); KYEONGJONG KIM, Yongin-si (KR); ISRAEL ESTEBAN LAZO MARTINEZ, Yongin-si (KR); JUNG-WOO LEE, Yongin-si (KR); JINHYEONG LEE, Yongin-si (KR)

(21) Appl. No.: 19/539,847

(22) Filed: Feb. 13, 2026

(30) Foreign Application Priority Data
Mar. 13, 2025 (KR) 10-2025-0032590

(51) Int. Cl. G02F 1/1333; G02F 1/1335; G02F 1/1368; H10K 59/131

(52) U.S. Cl. CPC G02F 1/133308; G02F 1/133512; G02F 1/1368; H10K 59/131

(57) ABSTRACT

A display module includes a base layer in which first to third light-emitting regions are defined, an input-sensing layer including reflection patterns respectively overlapping the light-emitting regions, and a light control layer including light-shielding patterns above the input-sensing layer and respectively overlapping the reflection patterns, color filters respectively covering the light-shielding patterns, and first to third refracting portions above the color filters and respectively at the first to third light-emitting regions, wherein a first distance from an end of the first refracting portion to an end of a first light-shielding pattern overlapping the first refracting portion, a second distance from an end of the second refracting portion to an end of a second light-shielding pattern overlapping the second refracting portion, and a third distance from an end of the third refractive portion to an end of a third light-shielding pattern overlapping the third refractive portion are different.

### CROSS-REFERENCE TO RELATED APPLICATION

The present application claims priority to, and the benefit of, Korean Patent Application No. 10-2025-0032590, filed on Mar. 13, 2025, in the Korean Intellectual Property Office, the entire disclosure of which is incorporated herein by reference.

### BACKGROUND

The present disclosure herein relates a display module with improved optical characteristics.

Multimedia devices, such as televisions, cell phones, tablets, navigations, gaming machines, and the like, include a display module that displays an image to a user through a display screen. The display module may include a display panel that generates an image, an input sensor that senses a user's touch, and the like.

At this time, external light may be reflected by the display module, or light emitted from the display module may be visually recognized from the side and visibility may be reduced.

### SUMMARY

The present disclosure provides a display module with improved optical properties. For example, the present disclosure provides a display module in which light emission efficiency is improved, and in which a color coordinate change phenomenon is reduced or prevented.

One or more embodiments of the present disclosure provide a display module including a base layer in which a first light-emitting region, a second light-emitting region, and a third light-emitting region are defined, an input-sensing layer including reflection patterns above the base layer, and respectively overlapping the first light-emitting region, the second light-emitting region, and the third light-emitting region, and a light control layer including light-shielding patterns above the input-sensing layer and respectively overlapping the reflection patterns, color filters respectively covering the light-shielding patterns, and a first refracting portion, a second refracting portion, and a third refracting portion above the color filters and respectively at the first light-emitting region, the second light-emitting region, and the third light-emitting region, wherein a first distance from an end of the first refracting portion to an end of a first one of the light-shielding patterns overlapping the first refracting portion, a second distance from an end of the second refracting portion to an end of a second one of the light-shielding patterns overlapping the second refracting portion, and a third distance from an end of the third refractive portion to an end of a third one of the light-shielding patterns overlapping the third refractive portion are different.

A refractive index of the first refracting portion, the second refracting portion, and the third refracting portion may be about 1.7 or more and about 2.5 or less.

The first distance may be about 2.7 times or more and about 3.3 times or less the third distance, wherein the second distance is about 1.8 times or more and about 2.2 times or less the third distance.

The third distance may be greater than or equal to about 1 um and less than or equal to about 3 um.

A thickness of the first refracting portion, a thickness of the second refracting portion, and a thickness of the third refracting portion may be about 1.5 um or more and about 2.0 um or less.

The first light-emitting region may be configured to provide a red light, wherein the second light-emitting region is configured to provide a green light, and wherein the third light-emitting region is configured to provide a blue light.

The first refracting portion, the second refracting portion, and the third refracting portion may have a shape of any one of a circle, a rectangle, or a trapezoid in plan view.

The first refracting portion, the second refracting portion, and the third refracting portion may respectively directly contact the color filters.

The input-sensing layer may include insulating layers, and sensing patterns between the insulating layers, wherein the reflection patterns are at a same layer as, and include a same material as, some of the sensing patterns.

The first refracting portion, the second refracting portion, and the third refracting portion may respectively include an organic lens.

The first refracting portion, the second refracting portion, and the third refracting portion may have a decreasing width in a direction away from the base layer.

The reflection patterns may have light reflectivity.

A width of the light-shielding patterns may be greater than a width of the reflection patterns, wherein a width of the first refracting portion, the second refracting portion, and the third refracting portion is greater than a width of the light-shielding patterns.

The display module may further include a display element layer including a pixel-defining layer defining pixel openings, and display elements at the pixel openings, and an overcoat layer covering the first refracting portion, the second refracting portion, and the third refracting portion, wherein the light control layer further includes a light-shielding partition wall overlapping the pixel-defining layer.

One or more embodiments of the present disclosure provide a display module including a base layer, a display element layer including a pixel-defining layer defining pixel openings above the base layer, and display elements at the pixel openings, an input-sensing layer including a reflection pattern above the display element layer and overlapping one of the pixel openings, and a light control layer including a light-shielding partition wall defining partition wall openings above the input-sensing layer and respectively overlapping the pixel openings, a first color filter, a second color filter, and a third color filter above the light-shielding partition wall, and a first refracting portion, a second refracting portion, and a third refracting portion respectively above the first color filter, the second color filter, and the third color filter, wherein a planar area of the first refracting portion is larger than a planar area of the second refracting portion, which is larger than a planar area of the third refracting portion.

A refractive index of the first refracting portion, the second refracting portion, and the third refracting portion may be about 1.7 or more and about 2.5 or less.

A distance from an end of the first refracting portion to an end of a first light-shielding pattern overlapping the first refracting portion in plan view may be a first distance, wherein a distance from an end of the second refracting portion to an end of a second light-shielding pattern overlapping the second refracting portion in plan view is a second distance, wherein a distance from an end of the third refracting portion to an end of a third light-shielding pattern overlapping the third refracting portion in plan view is a third distance, wherein the first distance is about 2.7 times or more and about 3.3 times or less the third distance, and wherein the second distance is about 1.8 times or more and about 2.2 times or less the third distance.

The third distance may be about 1 um or more and about 3 um or less, wherein a thickness of the first refracting portion, the second refracting portion, and the third refracting portion is about 1.5 um or more and about 2.0 um or less.

The base layer may include a first light-emitting region configured to provide a red light, a second light-emitting region configured to provide a green light, and a third light-emitting region configured to provide a blue light.

One or more embodiments of the present disclosure provide an electronic apparatus capable of providing an image, the electronic apparatus including a display module, a housing providing a base space for housing the display module, and a window above the display module, wherein the display module includes a base layer in which a first light-emitting region, a second light-emitting region, and a third light-emitting region are defined, an input-sensing layer including reflection patterns above the base layer and respectively overlapping the first light-emitting region, the second light-emitting region, and the third light-emitting region, a light control layer including light-shielding patterns above the input-sensing layer and respectively overlapping the reflection patterns, and color filters respectively covering the light-shielding patterns, and a first refracting portion, a second refracting portion, and a third refracting portion above the light control layer and respectively at the first light-emitting region, the second light-emitting region, and the third light-emitting region, wherein a first distance from an end of the first refracting portion to an end of a first one of the light-shielding patterns overlapping the first refracting portion, a second distance from an end of the second refracting portion to an end of a second one of the light-shielding patterns overlapping the second refracting portion, and a third distance from an end of the third refractive portion to an end of a third one of the light-shielding patterns overlapping the third refractive portion are different.

### BRIEF DESCRIPTION OF THE DRAWINGS

FIG. 1 is a block diagram of an electronic device according to one or more embodiments of the present disclosure.

FIG. 2 is a schematic diagram of an electronic device according to some embodiments of the present disclosure.

FIG. 3A is a perspective view of an electronic device according to one or more embodiments of the present disclosure.

FIG. 3B is an exploded perspective view of an electronic device according to one or more embodiments of the present disclosure.

FIG. 4 is a cross-sectional view of a display module according to one or more embodiments of the present disclosure.

FIG. 5 is an enlarged plan view of a portion of a display module according to one or more embodiments of the present disclosure.

FIG. 6 is a cross-sectional view of a display module taken along the line I-I′ in FIG. 5.

FIGS. 7-9 are enlarged views of a portion of FIG. 6.

FIGS. 10-12 are enlarged cross-sectional views of a portion of a display module according to one or more embodiments of the present disclosure.

FIG. 13 is an enlarged plan view of a portion of a display module according to one or more embodiments of the present disclosure.

FIG. 14 is an enlarged plan view of a portion of a display module according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

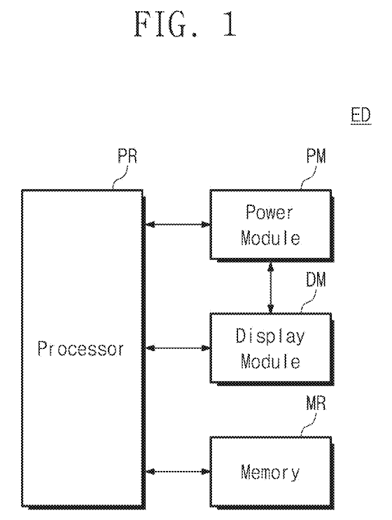

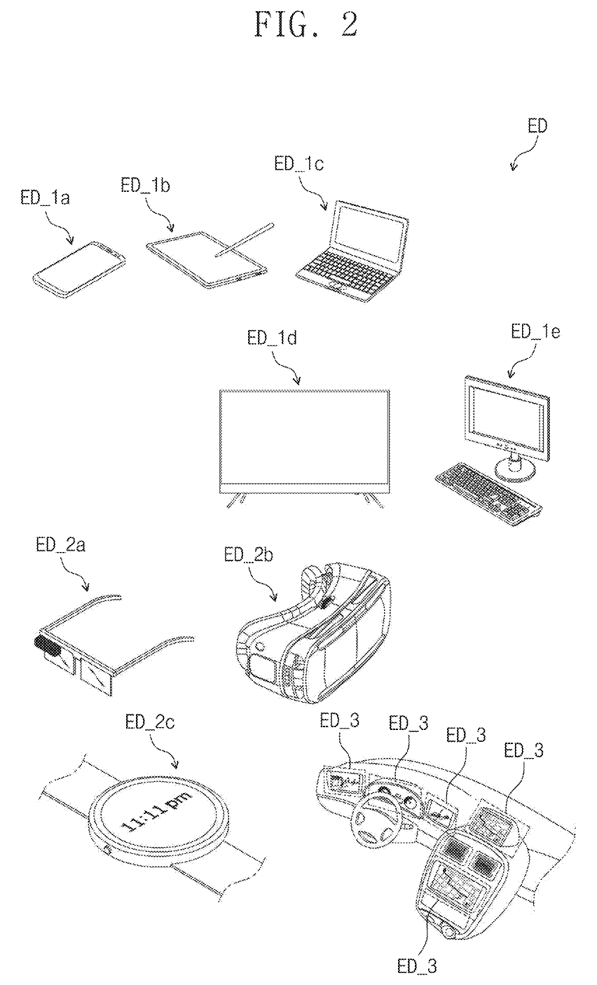

FIG. 1 is a block diagram of an electronic device according to one or more embodiments of the present disclosure. FIG. 2 is a schematic diagram of an electronic device according to some embodiments of the present disclosure.

The electronic device according to the present disclosure may be provided in various forms. The electronic device according to the present disclosure may further include a module or device having other additional functions.

Referring to FIG. 1, an electronic device ED according to one or more embodiments may include a display module DM, a processor PR, a memory MR, and a power module PM.

The processor PR may include at least one of a central processing unit (CPU), an application processor (AP), a graphics processing unit (GPU), a communication processor (CP), an image signal processor (ISP), or a controller.

The memory MR may store data information suitable for the operation of the processor PR or the display module DM. When the processor PR executes an application stored in the memory MR, an image data signal and/or an input control signal are transmitted to the display module DM, and the display module DM may process the received signal and output image information through a display screen.

The power module PM may include a power supply module, such as a power adapter or a battery device, and a power conversion module that converts power supplied by the power supply module to generate power required for operation of the electronic device ED.

Some of the individual modules functionally included in one module may be included in the display module DM, and the other may be provided in the electronic device ED separately from the display module DM.

FIG. 2 is a schematic diagram of an electronic device according to some embodiments of the present disclosure.

Referring to FIG. 2, an electronic device according to various embodiments may be an electronic device for image display, such as a smartphone ED-1a, a tablet PC ED-1b, a laptop ED-1c, a TV ED-1d, and a desk monitor ED-1e, a wearable electronic device including a display module, such as smart glasses ED-2a, a head-mounted display ED-2b, and a smart watch ED-2c, and an electronic device for a vehicle ED-3 including a display module, such as a CID (Center Information Display) and a room mirror display, located on an instrument panel, a center fascia, and a dashboard of a vehicle.

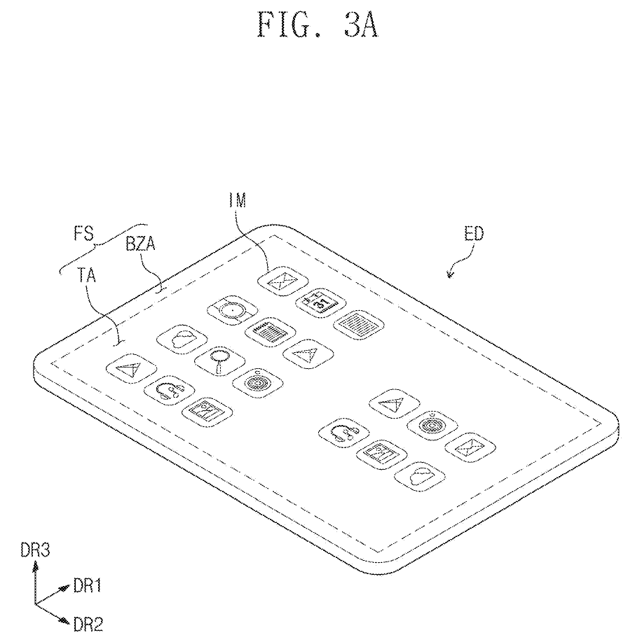

FIG. 3A is a perspective view of an electronic device according to one or more embodiments of the present disclosure. FIG. 3B is an exploded perspective view of an electronic device according to one or more embodiments of the present disclosure.

In one or more embodiments, the electronic device ED may have a rectangular shape having short sides extending in a first direction DR1, and long sides extending in a second direction DR2 on a plane. However, embodiments of the present disclosure are not limited thereto, and the electronic device ED may have various shapes, such as a circle, a polygon, and the like.

The electronic device ED may display an image IM in a third direction DR3 through a display surface FS parallel to the surface defined by the first direction DR1 and the second direction DR2. The third direction DR3 may be substantially parallel to the normal direction of the display surface FS. The display surface FS on which the image IM is displayed may correspond to a front surface of the electronic device ED. The image IM may include a still image as well as a dynamic image. FIG. 3A illustrates icon images as an example of an image IM.

In one or more embodiments, a front surface (or an upper surface) and a rear surface (or a lower surface) of each of members or units may be defined with reference to a direction in which the image IM is displayed. The front surface and the rear surface may be opposed to each other in the third direction DR3, and a normal direction of each of the front surface and the rear surface may be parallel to the third direction DR3. A separation distance between the front surface and the rear surface defined along the third direction DR3 may correspond to the thickness of the member (or unit).

In this specification, “on a plane” or “in plan view” may be defined as a state viewed in the third direction DR3. In this specification, “on a cross-section” may be defined as a state viewed in the first direction DR1 or the second direction DR2. Directions indicated by the first to third directions DR1, DR2, and DR3 may be converted to other directions as a relative concept.

The display surface FS on which the image IM is displayed on the electronic device ED may correspond to a front surface of the electronic device ED, and may correspond to a front surface FS of a window WP (see FIG. 3B). Hereinafter, the display surface and the front surface of the electronic device ED, and the front surface of the window WP will use the same reference numeral. On the other hand, in one or more embodiments, the electronic device ED may include a foldable display device including a folding region and a non-folding region, a bending display device including at least one bending portion, or the like.

Referring to FIG. 3B, the electronic device ED according to one or more embodiments may include a window WP, a display module DM, and a housing HAU.

The window WP may include an optically transparent insulating material. The window WP may include a transmission region TA and a bezel region BZA. The user may visually recognize an image provided through the transmission region TA corresponding to the front surface FS of the window WP.

The transmission region TA may be an optically transparent region. The bezel region BZA may be a region having a relatively low light transmittance compared to the transmission region TA. The bezel region BZA may have a color. The bezel region BZA is adjacent to the transmission region TA and may surround the transmission region TA. The bezel region BZA may define a shape of the transmission region TA. However, one or more embodiments of the present disclosure is not limited to that shown, the bezel region BZA may be located adjacent to only one side of the transmission region TA, or a portion of the bezel region BZA may be omitted.

In FIGS. 3A and 3B, the transmission region TA is shown in a square shape. However, this is illustrated as an example, and the transmissive region TA may have various shapes, and is not limited to any one embodiment.

The display module DM may be located under the window WP. The display module DM may be configured to substantially generate the image IM. The image IM generated by the display module DM is displayed on a display surface IS and visually recognized by the user from an outside through the transmission area TA.

The display module DM includes a display region DA and a non-display region NDA. The display region DA may be a region activated according to an electrical signal. The non-display region NDA may be a region covered by the bezel area BZA. The non-display region NDA is adjacent to the display region DA. The non-display region NDA may surround the display region DA.

The housing HAU may accommodate the display module DM. The housing HAU may provide a base space in which the display module DM is to be located. The housing HAU may be located to cover the display module DM so that an upper surface that is the display surface IS of the electronic device ED is exposed. The housing HAU may cover a side surface and a bottom surface of the display module DM, and may expose the entire upper surface. However, one or more embodiments of the present disclosure is not limited thereto, the housing HAU may cover a portion of the upper surface as well as the side surface and the bottom surface of the display module DM.

When the display module DM is viewed from the “front” side and the “side” side, paths which light arrives may be different from each other. In this case, when the display module DM is viewed from the “side,” the path of light may be longer than the path of light when viewed from the front. Accordingly, when the display module DM is viewed from the side, a phenomenon in which luminance decreases and color coordinates change may occur. The present disclosure includes a reflection pattern RP, a light-shielding pattern BD, and a refracting portions LS-R, LS-G, and LS-B having different respective planar areas, so that low reflection of the display module DM can be realized while reducing or minimizing luminance reduction and color coordinate change of the display module DM, as will be described below.

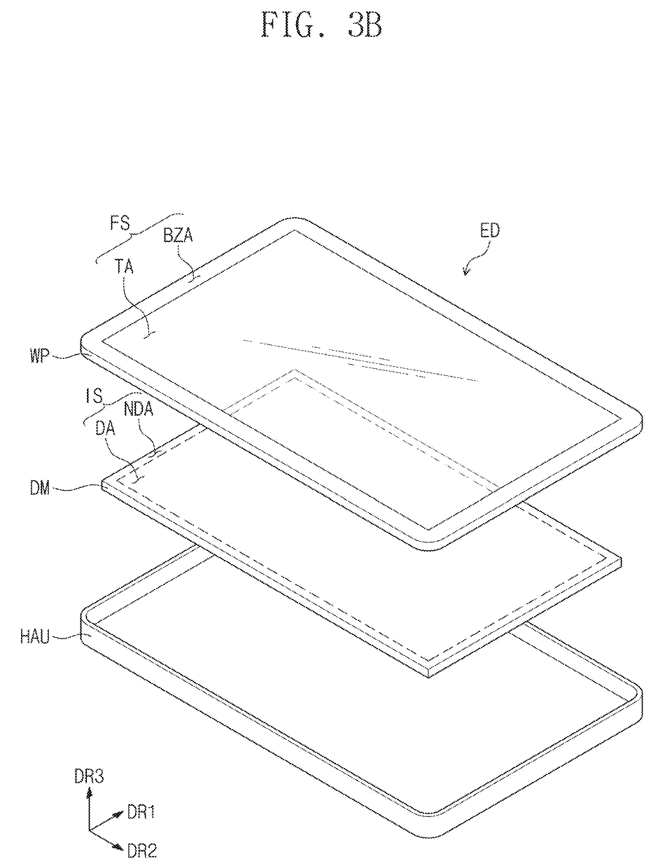

FIG. 4 is a cross-sectional view of a display module according to one or more embodiments of the present disclosure.

The display module DM according to one or more embodiments may include a display panel DP, an input-sensing layer ISU, a light control layer CCL, and an overcoat layer OC.

The display panel DP may include a base layer BS, a circuit element layer DP-CL, a display element layer DP-ED, and an encapsulation layer TFE.

The base layer BS may provide a base surface on which the circuit element layer DP-CL and the display element layer DP-ED are located. The base layer BS may be a glass substrate, a metal substrate, a polymer substrate, or the like. However, one or more embodiments of the present disclosure is not limited thereto, the base layer BS may be an inorganic layer, a functional layer, or a composite material layer. The base layer BS may have a multilayer structure.

The circuit element layer DP-CL may be located on the base layer BS (as used herein, “located on” may mean “above”). The circuit element layer DP-CL may include an insulating layer, a semiconductor pattern, a conductive pattern, a signal line, and the like. The insulating layer, a semiconductor layer, and a conductive layer are formed over the base layer BS by coating, vapor deposition, or the like, and then the insulating layer, the semiconductor layer, and the conductive layer may be selectively patterned through a plurality of photolithography processes. Then, the semiconductor pattern, the conductive pattern, and the signal line included in the circuit element layer DP-CL may be formed. In one or more embodiments, the circuit element layer DP-CL may include a transistor, a buffer layer, and insulating layers.

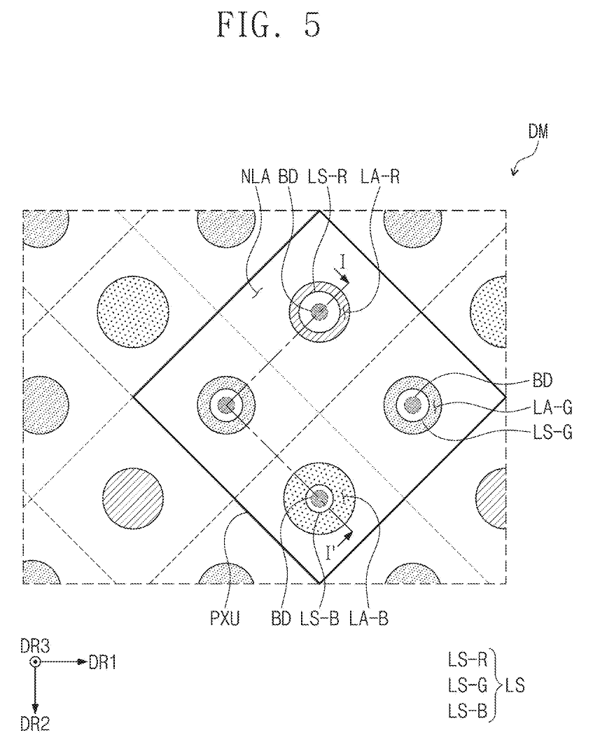

The display element layer DP-ED may be located on the circuit element layer DP-CL. The display element layer DP-ED may include a pixel-defining layer PDL (see FIG. 6) and a light-emitting device OLED (see FIG. 6), as will be described below.

The encapsulation layer TFE may be located on the display element layer DP-ED. The encapsulation layer TFE may cover the light-emitting device OLED. The encapsulation layer TFE may be a thin film encapsulation layer. The encapsulation layer TFE may be one layer or a plurality of layers stacked. The encapsulation layer TFE includes at least one insulating layer.

The encapsulation layer TFE according to one or more embodiments may include at least one inorganic film (hereinafter, an encapsulation inorganic film). In addition, the encapsulation layer TFE according to one or more embodiments may include at least one organic film (hereinafter, an encapsulation organic film) and at least one encapsulation inorganic film. The encapsulating inorganic film may protect the light-emitting device OLED from moisture/oxygen, and the encapsulating organic film may protect the light-emitting device OLED from foreign substances, such as dust particles.

The input-sensing layer ISU may be located on the encapsulation layer TFE. The input-sensing layer ISU may sense a user's touch, and may convert the touch into an electrical signal. The input-sensing layer IS may include inorganic layers and metal patterns located between the inorganic layers, as will be described below.

The light control layer CCL may be located on the input-sensing layer ISU. The light control layer CCL may block a portion of the light emitted from the display element layer DP-ED, thereby increasing a color purity of the light. The light control layer CCL may improve visibility of the display module DM by reflecting external light.

The overcoat layer OC may be located on the light control layer CCL. The overcoat layer OC may cover the light control layer CCL. Accordingly, the overcoat layer OC may improve a reliability of the light control layer CCL, as will be described below.

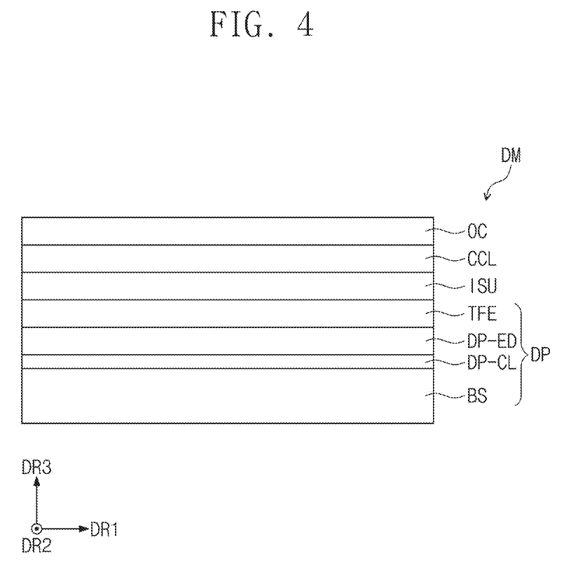

FIG. 5 is an enlarged plan view of a portion of a display module according to one or more embodiments of the present disclosure.

FIG. 5 may be a diagram illustrating a planar overlapping relationship between refracting portions LS, color filters CF-R, CF-G, and CF-B, and light-shielding patterns BD.

In one or more embodiments, pixel units PXU may be located in the display module DM. First to third light-emitting regions LA-R, LA-G, and LA-B may be defined in one pixel unit PXU. Also, non-light emitting region can be defined in one pixel unit PXU. FIG. 5 illustrates, as an example, that one of the first light-emitting region LA-R, two of the second light-emitting regions LA-G, and one of the third light-emitting region LA-B are defined in one pixel unit PXU. However, the number and arrangement of light-emitting regions included in one pixel unit PXU are not limited to those shown.

The display module DM according to one or more embodiments may provide different lights through the first to third light-emitting regions LA-R, LA-G, and LA-B. Light provided by the second light-emitting region LA-G may have a longer wavelength than light provided by the third light-emitting region LA-B, and light provided by the first light-emitting region LA-R may have a longer wavelength than light provided by a second light-emitting region LA-G. For example, the display module DM may provide red light in the first light-emitting region LA-R, green light in the second light-emitting region LA-G, and blue light in the third light-emitting region LA-B.

The first to third refracting portions LS-R, LS-G, and LS-B may overlap the first to third light-emitting regions LA-R, LA-G, and LA-B, respectively.

The first to third refracting portions LS-R, LS-G, and LS-B may be lenses. For example, each of the first to third refracting portions LS-R, LS-G, and LS-B may be an organic lens, a glass lens, or the like. Each of the first to third refracting portions LS-R, LS-B, and LS-G may be a convex lens. Accordingly, the first to third refracting portions LS-R, LS-G, and LS-B may change paths of light emitted from the first to third light-emitting regions LA-R, LA-G, and LA-B, respectively.

The first to third refracting portions LS-R, LS-G, and LS-B may be circular in a plane (e.g., in plan view). However, embodiments of the present disclosure are not limited to those shown. For example, the first to third refracting portions LS-R, LS-G, and LS-B may have an elliptical shape, a polygonal shape, or the like on a plane, as will be described below.

On a plane, the first refracting portion LS-R may have an area that is smaller than that of the first light-emitting region LA-R. The second refracting portion LS-G may have an area that is smaller than that of the second light-emitting region LA-G. The third refracting portion LS-B may have an area that is smaller than that of the third light-emitting region LA-B.

A planar area of the first refracting portion LS-R may be larger than a planar area of a second refracting portion LS-G. The planar area of the second refracting portion LS-G may be larger than the planar area of a third refracting portion LS-B.

Light-shielding patterns BD may be located to overlap the first to third refracting portions LS-R, LS-G, and LS-B, respectively. An area of each of the light-shielding patterns BD may be smaller than an area of the first to third refracting portions LS-R, LS-G, and LS-B that each overlap.

The light-shielding patterns BD may absorb external light, and may reduce or prevent degradation of visibility of the display module DM due to reflection of the external light. In addition, because the display module DM according to present disclosure include the refracting portions LS-R, LS-G, and LS-B, reflection of external light may be reduced, and luminance of the display module DM when viewed from the front may be compensated, as will be described below.

FIG. 6 is a cross-sectional view of a display module taken along the line I-I′ in FIG. 5.

The light-emitting device OLED may include a first electrode EL1, a second electrode EL2 facing the first electrode EL1, and light-emitting layers EML-R, EML-G and EML-B located between respective ones of the first electrodes EL1 and the second electrode EL2.

In one or more embodiments, the light-emitting layers EML-R, EML-G, and EML-B may include an organic light-emitting material. The light-emitting device OLED may further include a hole transport region HTR, an electron transport region ETR, and a capping layer CPL.

The pixel-defining layer PDL may be located on the circuit element layer DP-CL (as used herein, “located on” may mean “above”). The pixel-defining layer PDL may cover a portion of the first electrode EL1. A pixel opening OH may be defined in the pixel-defining layer PDL. The pixel opening OH may expose at least a portion of the first electrode EL1. A region where the first electrode EL1 is exposed by the pixel opening OH may be defined as a “light-emitting region”.

The pixel-defining layer PDL may include a polymer resin. For example, the pixel-defining layer PDL may include a polyacrylate-based resin or a polyimide-based resin. In addition, the pixel-defining layer PDL may include a light-absorbing material, or may include black pigment or black dye, for example, carbon black. In addition, the pixel-defining layer PDL may include an inorganic material. For example, the pixel- defining layer PDL may include an inorganic material, such as silicon nitride (SiNx), silicon oxide (SiOx), and silicon nitride oxide (SiOxNy).

The first electrode EL1 may be located on the circuit element layer DP-CL. The first electrode EL1 may be an anode or a cathode. The first electrode EL1 may be a pixel electrode. The first electrode EL1 may be a transmissive electrode, a semi-transmissive electrode, or a reflective electrode.

The second electrode EL2 may be located on the first electrode EL1. The second electrode EL2 may be a cathode or an anode. In one or more embodiments, when the first electrode EL1 is an anode, the second electrode EL2 may be a cathode. In one or more embodiments, when the first electrode EL1 is a cathode, the second electrode EL2 may be an anode. The second electrode EL2 may be a common electrode. However, embodiments are not limited thereto. The second electrode EL2 may be a transmissive electrode, a semi-transmissive electrode, or a reflective electrode.

The light-emitting device OLED may further include a hole transport region HTR and an electron transport region ETR. In one or more embodiments, the light-emitting device OLED may further include a capping layer located on the second electrode EL2.

The input-sensing layer ISU may be located on the encapsulation layer TFE. The input-sensing layer ISU may include insulating layers INL1 and INL2, reflection patterns RP, and a sensing pattern YM.

The reflection patterns RP may be formed through the same process (e.g., at a same layer) as some of the sensing patterns YM, and may include the same material. The reflective patterns RP may comprise a metallic material.

The reflection patterns RP may have light reflectivity. The reflection patterns RP may cause light emitted from the light-emitting layers EML-R, EML-G, and EML-B to be reflected and recycled. Accordingly, the light efficiency of the display module DM may be increased.

The light control layer CCL may be located on the input-sensing layer ISU. The light control layer CCL may include the light-shielding patterns BD, light-shielding partition walls BP, color filters CF-R, CF-G, and CF-B, and the first to third refracting portions LS-R, LS-G, and LS-B.

The light-shielding patterns BD may overlap the reflection patterns RP, respectively. A width of the light-shielding patterns BD may be greater than a width of the reflection patterns RP.

The light-shielding partition wall BP may be located on the input-sensing layer ISU. A partition wall opening BP-OP, through which light emitted from the light-emitting layers EML-R, EML-G, and EML-B may enter and exit, may be defined in the light-shielding partition wall BP.

The color filters CF-R, CF-G, and CF-B may cover the light-shielding patterns BD and the light-shielding partition walls BP. The color filters CF-R, CF-G, and CF-B may overlap the light-shielding patterns BD.

The first to third refracting portions LS-R, LS-G, and LS-B may be located on the color filters CF-R, CF-G, and CF-B, respectively. The first to third refracting portions LS-R, LS-G, and LS-B may respectively directly contact the color filters CF-R, CF-G, and CF-B.

The first to third refracting portions LS-R, LS-G, and LS-B may have a smaller width in a direction away from the base layer BS. The first to third refracting portions LS-R, LS-G, and LS-B may have a decreasing width in the third direction DR3.

The refractive index of each of the first to third refracting portions LS-R, LS-G, and LS-B may be about 1.7 or more and about 2.5 or less.

The overcoat layer OC may be located on the first to third refracting portions LS-R, LS-G, and LS-B and the color filters CF-R, CF-G, and CF-B. The overcoat layer OC may cover the first to third refracting portions LS-R, LS-G, and LS-B and the color filters CF-R, CF-G, and CF-B.

The overcoat layer OC may have a substantially flat upper surface. In addition, a lower surface of the overcoat layer OC may compensate for a step due to elements located under the overcoat layers OC. The overcoat layer OC may comprise an organic material. For example, the overcoat layer OC may include any one or more of a polyacrylic resin, a polyimide resin, an acrylic resin, an epoxy resin, and an acrylate resin.

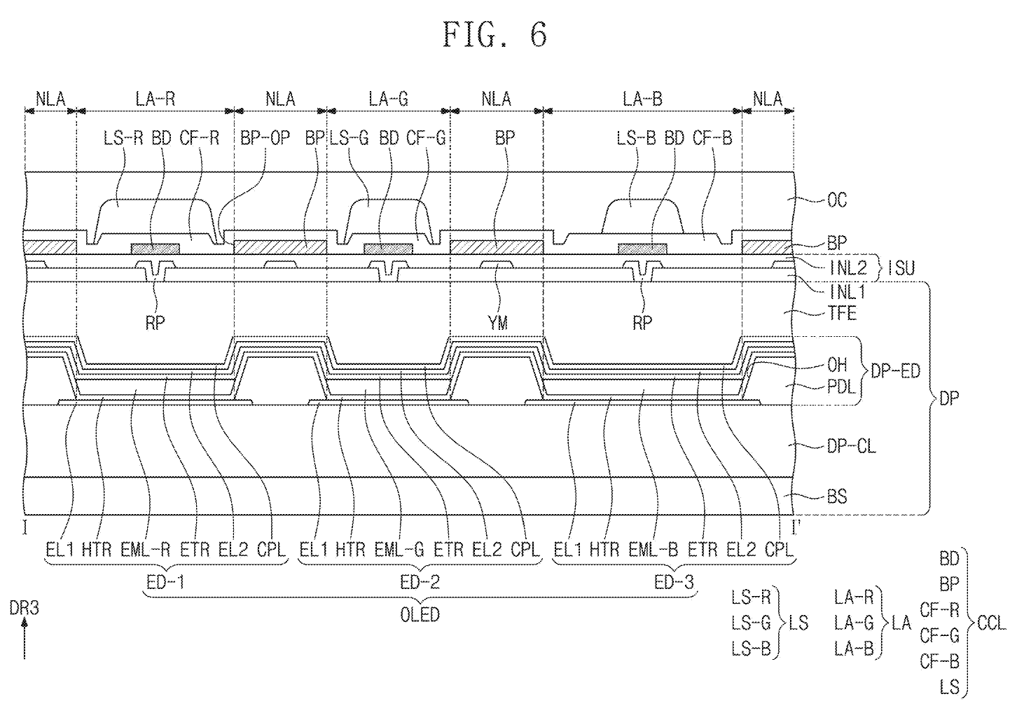

FIGS. 7-9 are enlarged views of a portion of FIG. 6.

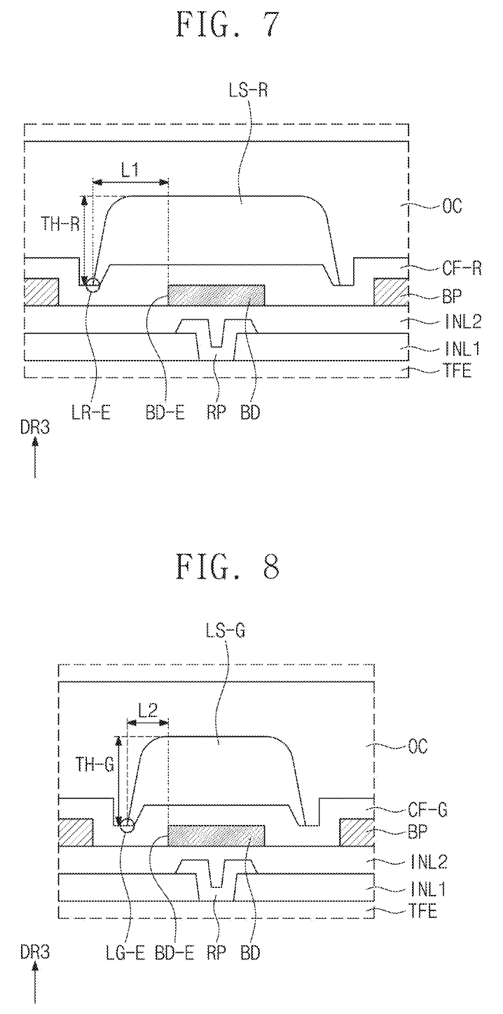

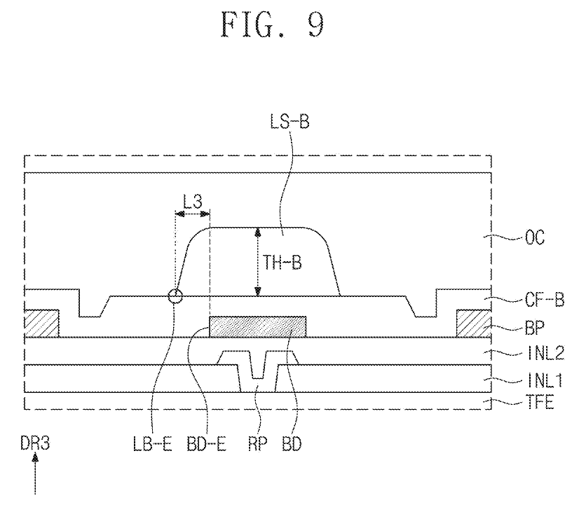

FIG. 7 is an enlarged view of the first light-emitting region LA-R of FIG. 6, FIG. 8 is an enlarged view the second light-emitting region LA-G of FIGS. 6, and 9 is an enlarged view a third light-emitting region LA-B of FIG. 6.

Hereinafter, structures and effects of the first to third refracting portions LA-R, LA-G, and LA-B will be described with reference to FIGS. 7-9.

In this specification, a distance from an end LR-E of the first refracting portion LS-R to an end BD-E of the light-shielding pattern BD overlapping the first refracting portion LS-R on a plane (e.g., in plan view) may be defined as a first distance L1. A distance from an end LR-E of the second refracting portion LS-G to an end BD-E of the light-shielding pattern BD overlapping the second refracting portion LS-G on a plane may be defined as a second distance L2. A distance from an end LR-E of the third refracting portion LS-B to an end BD-E of the light-shielding pattern BD overlapping the third refracting portion LS-B on a plane may be defined as a third distance L3.

The first distance L1 may be greater than or equal to about 2.7 times and less than or equal to about 3.3 times the third distance L3. The second distance L2 may be greater than or equal to about 1.8 times and less than or equal to about 2.2 times the third distance L3. For example, the first distance L1, the second distance L2, and the third distance L3 may sequentially have a ratio of 3:2:1.

In this case, the third distance L3 may be greater than or equal to about 1 um and less than or equal to about 3 um.

Thicknesses TH-R, TH-G, and TH-B of the first to third refracting portions LS-R, LS-G, and LS-B may be about 1.5 um or more and about 2.0 um or less, respectively.

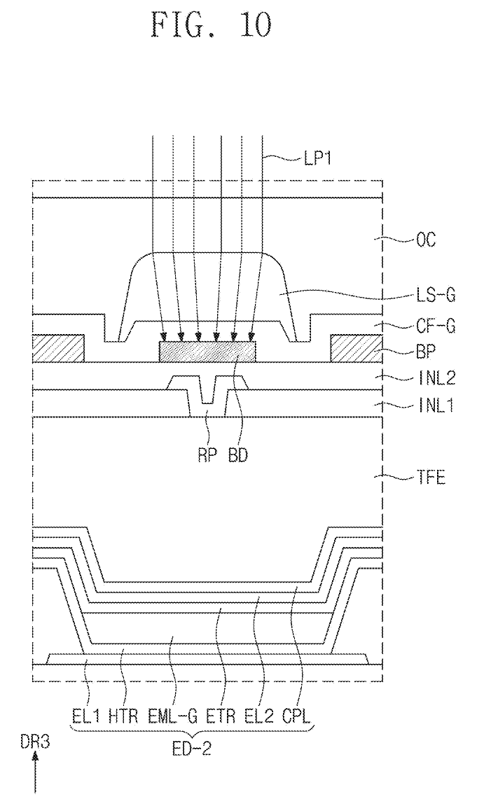

FIGS. 10-12 are enlarged cross-sectional views of a portion of a display module according to one or more embodiments of the present disclosure.

FIGS. 10-12 are enlarged views of a second refracting portion LS-G according to one or more embodiments of the present disclosure. The same/similar content as the content described with reference to the second refracting portion LS-G may be applied to the first refracting portion LS-R and the third refracting portion LS-B.

FIG. 10 may be a diagram for explaining that the “external light reflection phenomenon” is reduced in the display module DM according to the present disclosure. In this specification, the “external light reflection phenomenon” may be defined as a phenomenon in which, when the display module DM is exposed to external light, external light is reflected to an electrode or the like included in the display module DM.

FIG. 10 illustrates, as an example, that the first light LP1 approaches the display module DM. The first light LP1 may also be referred to herein as “external light LP1”.

When the conventional display module is exposed to external light LP1, the external light LP1 is reflected by an electrode or the like included in the display module to be visually recognized by a user. As a result, a visibility of, or visual quality of, a conventional display module has been reduced.

However, the display module DM according to the present disclosure includes the second refracting portion LS-G and the light-shielding pattern BD, so that the “external light reflection phenomenon” may be reduced.

For example, the external light LP1 coming toward the display module DM may be refracted by the second refracting portion LS-G. The second refracting portion LS-G may concentrate light toward a focal point. The light-shielding pattern BD may be located between the second refracting portion LS-G and the focal point of the second refracting portion LS-G. The light-shielding pattern BD may absorb the external light LP1. Accordingly, reflection of the external light LP1 may be reduced or prevented.

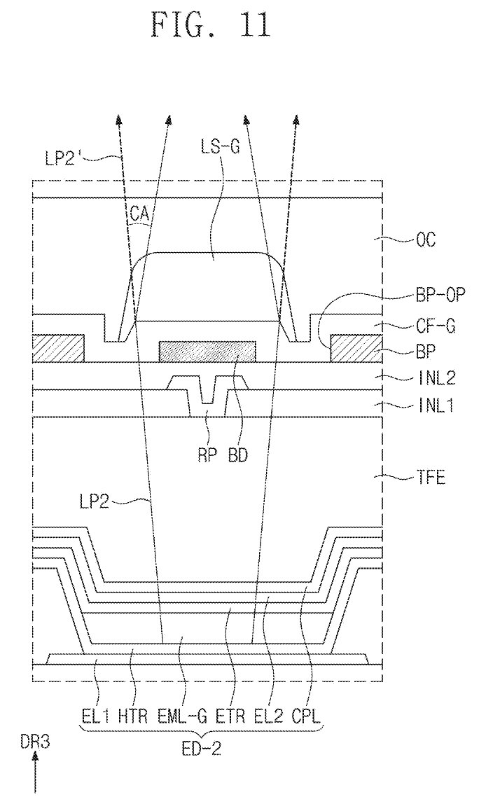

FIG. 11 may be a diagram for explaining that the display module DM according to the present disclosure reduces a “white angular dependency (WAD)” phenomenon.

A portion of the second light LP2 passing through the partition wall opening BP-OP among the light emitted from the light-emitting layer EML-G may be refracted by the second refracting portion LS-G by a refracting angle CA. Accordingly, the second light LP2, which is originally to be viewed in a lateral direction in a second light path LP2′, may be viewed in a front direction by the second refracting portion LS-G. Accordingly, a luminance at the front surface is increased, the phenomenon of “white angular dependency” is effectively reduced or prevented, and a problem of changing a color tone may be reduced or prevented.

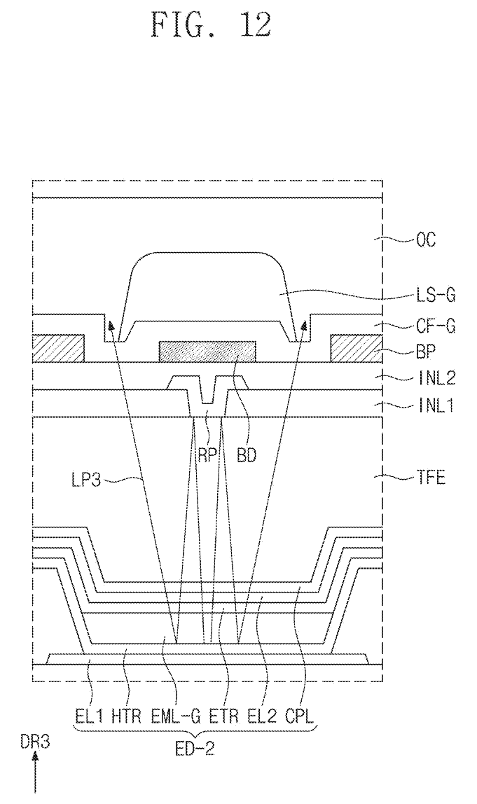

FIG. 12 may be a diagram for describing a “light recycling” phenomenon of the display module DM according to the present disclosure.

In the display module DM according to the present disclosure, because the reflection pattern RP overlapping the light-shielding pattern BD is located under the light-shielding patterns BD, a third light LP3 emitted from the second light-emitting layer EML-G may not be blocked, or absorbed, by the light-shielding pattern BD, but instead may be reflected by the reflection patterns RP. The reflected third light LP3 may be reflected again, or re-reflected, by the first electrode EL1 or the like and emitted to an outside. In one or more embodiments, the third light LP3 may be emitted to the outside after the ‘reflection’ and the ‘re-reflection’ are additionally performed. A portion of the light emitted from the second light-emitting layer EML-G is “light recycled,” so that the light emission efficiency of the display module DM may be improved.

As described above, the display module DM according to the present disclosure may have improved optical characteristics by including the reflection pattern RP, the light-shielding pattern BD, and the second refracting portion LS-G. However, when the size of the refracting portions LS-R, LS-G, and LS-B increases, a problem may occur in that the reflection of the external light LP1 (see FIG. 10) is rather increased by the surface of the refracting portions LS-R, LS-G, and LS-B.

Accordingly, the present disclosure can be directed to providing a relatively large refracting portion in a long wavelength region where a color coordinate change problem is likely to occur. For example, in the present disclosure, the refracting portion LS-R having the largest size may overlap the first light-emitting region LA-R in which a problem of a decrease in luminance and a change in color coordinates is likely to occur, and the refracting portion LS-B having the smallest size may be located in the third light-emitting region LA-B in which the problem of a decrease of luminance and the change in color coordinate is unlikely to occur. Therefore, according to the present disclosure, it is possible to reduce or minimize reflection by surfaces of the refracting portions LS-R, LS-G, and LS-B while reducing the problem of luminance decrease and color coordinate change.

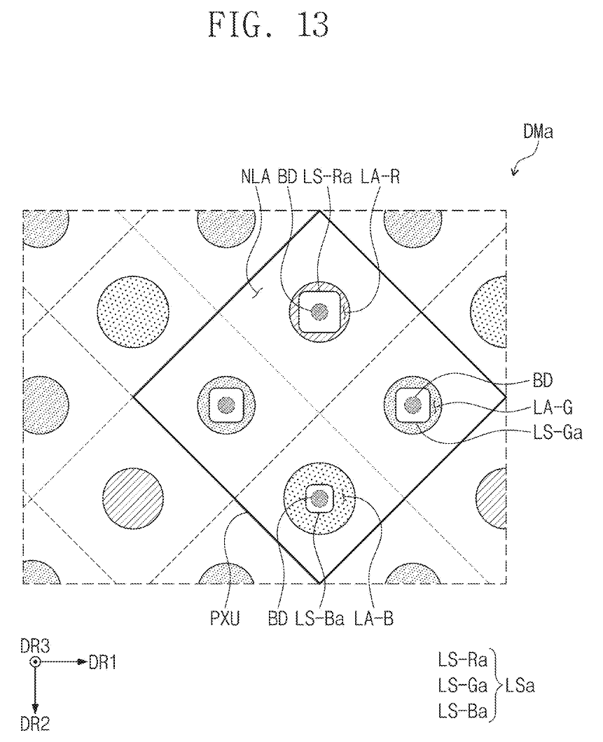

FIG. 13 is an enlarged plan view of a portion of a display module according to one or more embodiments of the present disclosure.

The same/similar elements as those described with reference to FIGS. 1-12 are denoted by the same/similar reference numerals, and the descriptions thereof will be omitted, and the differences will be mainly described.

A display module DMa according to one or more embodiments may include a pixel unit PXU. First to third light-emitting regions LA-R, LA-G, and LA-B may be defined in the pixel unit PXU. First to third refracting portions LS-Ra, LS-Ga, and LS-Ba may overlap the first to third light-emitting regions LA-R, LA-G, and LA-B.

On a plane, the first to third refracting portions LS-Ra, LS-Ga, and LS-Ba may each have a rectangular shape. Although FIG. 13 illustrates that planar shapes of the first to third refracting portions LS-Ra, LS-Ga, and LS-Ga are chamfered shapes as an example, one or more embodiments is not limited thereto.

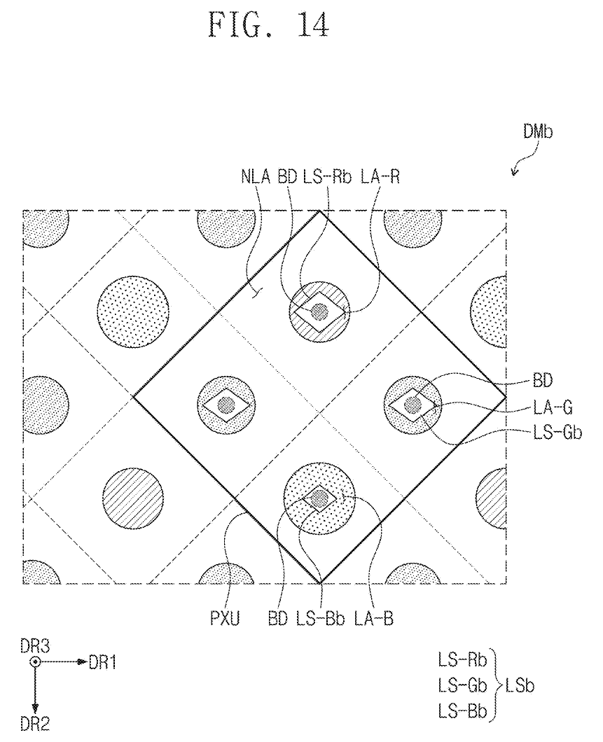

FIG. 14 is an enlarged plan view of a portion of a display module according to one or more embodiments of the present disclosure.

The same/similar elements as those described with reference to FIGS. 1-12 are denoted by the same/similar reference numerals, and the descriptions thereof will be omitted, and the differences will be mainly described.

A display module DMa according to one or more embodiments may include a pixel unit PXU. First to third light-emitting regions LA-R, LA-G, and LA-B may be defined in the pixel unit PXU. The first to third refracting portions LS-Rb, LS-Gb, and LS-Bb may overlap the first to third light-emitting regions LA-R, LA-G, and LA-B.

Although embodiments of the present disclosure have been described above, it will be understood that those skilled in the art or those skilled in the relevant art may make various modifications and changes to the present disclosure without departing from subject matter of the present disclosure described in the claims. Therefore, the present disclosure should not be limited to the contents described in the detailed description of the specification, but should be determined by the claims, with functional equivalents thereof to be included therein.

What is claimed is:

1. A display module comprising:
a base layer in which a first light-emitting region, a second light-emitting region, and a third light-emitting region are defined;
an input-sensing layer comprising reflection patterns above the base layer, and respectively overlapping the first light-emitting region, the second light-emitting region, and the third light-emitting region; and
a light control layer comprising:
light-shielding patterns above the input-sensing layer and respectively overlapping the reflection patterns;
color filters respectively covering the light-shielding patterns; and
a first refracting portion, a second refracting portion, and a third refracting portion above the color filters and respectively at the first light-emitting region, the second light-emitting region, and the third light-emitting region,
wherein a first distance from an end of the first refracting portion to an end of a first one of the light-shielding patterns overlapping the first refracting portion, a second distance from an end of the second refracting portion to an end of a second one of the light-shielding patterns overlapping the second refracting portion, and a third distance from an end of the third refractive portion to an end of a third one of the light-shielding patterns overlapping the third refractive portion are different.

2. The display module of claim 1, wherein a refractive index of the first refracting portion, the second refracting portion, and the third refracting portion is about 1.7 or more and about 2.5 or less.

3. The display module of claim 1, wherein the first distance is about 2.7 times or more and about 3.3 times or less the third distance, and
wherein the second distance is about 1.8 times or more and about 2.2 times or less the third distance.

4. The display module of claim 3, wherein the third distance is greater than or equal to about 1 um and less than or equal to about 3 um.

5. The display module of claim 1, wherein a thickness of the first refracting portion, a thickness of the second refracting portion, and a thickness of the third refracting portion is about 1.5 um or more and about 2.0 um or less.

6. The display module of claim 1, wherein the first light-emitting region is configured to provide a red light,
wherein the second light-emitting region is configured to provide a green light, and
wherein the third light-emitting region is configured to provide a blue light.

7. The display module of claim 1, wherein the first refracting portion, the second refracting portion, and the third refracting portion have a shape of any one of a circle, a rectangle, or a trapezoid in plan view.

8. The display module of claim 1, wherein the first refracting portion, the second refracting portion, and the third refracting portion respectively directly contact the color filters.

9. The display module of claim 1, wherein the input-sensing layer comprises insulating layers, and sensing patterns between the insulating layers, and
wherein the reflection patterns are at a same layer as, and comprise a same material as, some of the sensing patterns.

10. The display module of claim 1, wherein the first refracting portion, the second refracting portion, and the third refracting portion respectively comprise an organic lens.

11. The display module of claim 1, wherein the first refracting portion, the second refracting portion, and the third refracting portion have a decreasing width in a direction away from the base layer.

12. The display module of claim 1, wherein the reflection patterns have light reflectivity.

13. The display module of claim 1, wherein a width of the light-shielding patterns is greater than a width of the reflection patterns, and
wherein a width of the first refracting portion, the second refracting portion, and the third refracting portion is greater than a width of the light-shielding patterns.

14. The display module of claim 1, further comprising:
a display element layer comprising a pixel-defining layer defining pixel openings, and display elements at the pixel openings; and
an overcoat layer covering the first refracting portion, the second refracting portion, and the third refracting portion,
wherein the light control layer further comprises a light-shielding partition wall overlapping the pixel-defining layer.

15. A display module comprising:
a base layer;
a display element layer comprising a pixel-defining layer defining pixel openings above the base layer, and display elements at the pixel openings;
an input-sensing layer comprising a reflection pattern above the display element layer and overlapping one of the pixel openings; and
a light control layer comprising a light-shielding partition wall defining partition wall openings above the input-sensing layer and respectively overlapping the pixel openings, a first color filter, a second color filter, and a third color filter above the light-shielding partition wall, and a first refracting portion, a second refracting portion, and a third refracting portion respectively above the first color filter, the second color filter, and the third color filter,
wherein a planar area of the first refracting portion is larger than a planar area of the second refracting portion, which is larger than a planar area of the third refracting portion.

16. The display module of claim 15, wherein a refractive index of the first refracting portion, the second refracting portion, and the third refracting portion is about 1.7 or more and about 2.5 or less.

17. The display module of claim 15, wherein a distance from an end of the first refracting portion to an end of a first light-shielding pattern overlapping the first refracting portion in plan view is a first distance,
wherein a distance from an end of the second refracting portion to an end of a second light-shielding pattern overlapping the second refracting portion in plan view is a second distance,
wherein a distance from an end of the third refracting portion to an end of a third light-shielding pattern overlapping the third refracting portion in plan view is a third distance,
wherein the first distance is about 2.7 times or more and about 3.3 times or less the third distance, and
wherein the second distance is about 1.8 times or more and about 2.2 times or less the third distance.

18. The display module of claim 17, wherein the third distance is about 1 um or more and about 3 um or less, and
wherein a thickness of the first refracting portion, the second refracting portion, and the third refracting portion is about 1.5 um or more and about 2.0 um or less.

19. The display module of claim 15, wherein the base layer comprises:
a first light-emitting region configured to provide a red light;
a second light-emitting region configured to provide a green light; and
a third light-emitting region configured to provide a blue light.

20. An electronic apparatus capable of providing an image, the electronic apparatus comprising:
a display module;
a housing providing a base space for housing the display module; and
a window above the display module,
wherein the display module comprises:
a base layer in which a first light-emitting region, a second light-emitting region, and a third light-emitting region are defined;
an input-sensing layer comprising reflection patterns above the base layer and respectively overlapping the first light-emitting region, the second light-emitting region, and the third light-emitting region;
a light control layer comprising light-shielding patterns above the input-sensing layer and respectively overlapping the reflection patterns, and color filters respectively covering the light-shielding patterns; and
a first refracting portion, a second refracting portion, and a third refracting portion above the light control layer and respectively at the first light-emitting region, the second light-emitting region, and the third light-emitting region,
wherein a first distance from an end of the first refracting portion to an end of a first one of the light-shielding patterns overlapping the first refracting portion, a second distance from an end of the second refracting portion to an end of a second one of the light-shielding patterns overlapping the second refracting portion, and a third distance from an end of the third refractive portion to an end of a third one of the light-shielding patterns overlapping the third refractive portion are different.
